(19) United States
(12) Patent Application Publication
(10) Pub. No.: US 2024/0209493 A1
(43) Pub. Date: Jun. 27, 2024

(54) METHOD FOR DEPOSITION OF DENSE CHROMIUM ON A SUBSTRATE

(71) Applicant: Hydromecanique Et Frottement, Andrezieux-Boutheon (FR)

(72) Inventors: Christophe Heau, Saint-Jean-Bonnefonds (FR); Maxime Villard, Chazelles-Sur-Lyon (FR)

(21) Appl. No.: 18/557,430

(22) PCT Filed: Mar. 21, 2022
(86) PCT No.: PCT/FR2022/050517

§ 371 Date: Oct. 26, 2023

(30) Foreign Application Priority Data
May 19, 2021 (FR) FR2105207

(51) Int. Cl. C23C 14/34; C23C 14/00; C23C 14/02; C23C 14/06; C23C 14/35; C23C 14/50; G21C 3/07; G21C 21/02; H01J 37/32; H01J 37/34

(52) U.S. Cl. CPC C23C 14/345; C23C 14/0036; C23C 14/025; C23C 14/0641; C23C 14/357; C23C 14/505; G21C 3/07; G21C 21/02; H01J 37/3244; H01J 37/3405; H01J 37/3426; H01J 2237/332

(57) ABSTRACT

The invention relates to a method for depositing a chromium-based material from a target onto a metal substrate, by continuous magnetron sputtering, using a plasma generated in a gas.

According to the invention:
the ratio between the flow of gaseous ions directed toward the substrate and the flow of neutral chromium atoms directed toward the substrate is adjusted to between 0.5 and 1.7; and
a bias voltage of between −50V and −100V is applied to the substrates.

### BACKGROUND

### Technical Field

The invention relates to the technical field of surface vacuum treatment, and in particular, physical vapour deposition of chromium on a substrate.

### Prior Art

The oxidation resistance properties of chromium are well-known from the prior art. In the particular case of nuclear reactors, chromium forms part of the materials used to coat fuel sheaths, such that these are best protected from oxidation by water or by water vapour.

Indeed, these fuel sheaths are generally made of zirconium or zirconium alloy, which has very good oxidation resistance features, up to temperatures of around 300° C. However, in case of water supply failure of a nuclear reactor, the water from the reactor can be led to pass to the vapour state, which considerably reduces the discharging effectiveness of the calories released by the fuel sheaths. This results in a significant increase in temperature of the fuel sheaths, which then become subjected to oxidation.

The oxidation of the zirconium alloy by the water vapour releases significant quantities of hydrogen, which can, on the one hand, weaken the zirconium alloy of the sheath, and on the other hand, lead to an explosion of the hydrogen, when its concentration in the air above the reactor becomes critical.

In order to protect the zirconium from oxidation at a high temperature, it has therefore been considered to deposit on the external part of the fuel sheaths, a chromium- or chromium nitride-based protective layer. Such a layer, in order to correctly fulfil its function, must be “dense”, i.e. have as few porosities as possible.

Among the different technologies which can be considered, those by vacuum deposition are favoured, as contrary to electroplating, they do not implement dangerous pollutants, such as chromium VI. However, the different vacuum deposition techniques are not equivalent, either because their productivity is not adapted to industrial expectation, or because their scale extension is not possible. Indeed, in the particular case of fuel sheaths, this relates to coating tubes of several metres long, typically around 5 m long and 10 mm in diameter.

Among the industrial vacuum deposition techniques, cathodic arc evaporation could be chosen. However, this is not necessarily adapted to the problem in question, as on the one hand, this technique is considered to induce defects in the formed layers, these defects being known as droplets. These molten metal droplets are projected by the arc over the parts being coated and generate growth defects, which damages the performance of the coating.

On the other hand, this technique requires a very high number of deposition sources to cover the height of the deposition machine, which would typically be around 30 circular sources for a 5 m-long substrate. Further to the high cost of such a number of sources, if they were powered simultaneously, they would require a bias current of the parts during the deposition of several hundred amperes, thus exceeding even broadly the current of an arc which would accidentally ignite, on the parts during one of the treatment steps.

Thus poses an industrialisation problem, as the bias generators do not cover this current range. This problem could be bypassed by only making a few sources operate simultaneously, for example three, to limit the bias current. The sources would thus operate by intermittence to cover the height of the machine. However, this would generate a considerable drop in productivity by greatly reducing the deposition speed.

The closed field magnetron sputtering technique has also been used to produce dense chromium layers (see, for example, the document, “Surface and Coatings Technology”, vol. 389 (2020), no. 125618). This technique uses the plasma of the deposition cathode for densification. The disadvantage is that this magnetic configuration reduces the rate of using sputtering targets. In addition, the intensity of the ion bombardment depends on the magnetic configuration and is not easily adjusted.

The conventional magnetron technique, also called magnetron sputtering, makes it possible to coat long substrates of several metres, by using generators of a power of around 100 kW (kilowatts). Their use is, for example, well-known in the glass industry to in-process coat glass plates of several metres wide. The bias current of the parts is modest and the generators on the market are adapted for this purpose. The layers also have no droplet-type defects, since this technology does not generate any.

However, the conventional magnetron layers obtained have a column growth, where pores develop along the columns, as illustrated, in particular, in the article, “Protective coatings on zirconium-based alloys as accident-tolerant fuel (ATF) claddings”, FIG. 5. A. The quality of the layer is therefore not satisfactory.

Document EP3195322 recommends the use of a variant of the magnetron deposition technology, high power impulse magnetron sputtering (HIPIMS). In this technique, short and very-low-power pulses are applied to the sputtering target. These short pulses make it possible, on the one hand, for a partial ionisation of the sputtered metal, and on the other hand, the ionisation of a part of the argon. The bias of the parts during the deposition enables a densification of the layers by these ions. With respect to conventional magnetron, the yield of the HIPIMS is less good. This partially lies in the fact that certain metal ions fall back onto the cathode and are therefore not available for the coating. Generally, the loss of yield is between 10% and 50% with respect to the deposition speed of conventional magnetron.

The HIPIMS technique, although technically viable, generates large difficulties for industrialisation, in particular when this relates to treating substrates of several metres long. Indeed, HIPIMS generators are very expensive and the maximum average powers of the available generators are around 20 to 30 kW. With three to five times less power than a conventional magnetron, the deposition speed becomes particularly slow and considerably encumbers productivity.

Moreover, the HIPIMS technique requires substrate carrier bias generators, which are particular. Conventional generators are indeed inefficient, due to the high increase in intensity corresponding to the ion current arriving on the substrate during the pulse. This high increase in intensity generates a sudden drop in impedance of the plasma, thus making the bias voltage of the generator drop to 0V. The ions are thus not accelerated. To bypass this problem, an HIPIMS generator for the bias of the parts is used. Its pulses are synchronised with those of the deposition generator, which gives an additional complexity to the industrial deposition device.

Although the choice of the material to be deposited is important to resist corrosion, this criterion does not suffice, and the structure and the appearance of this material must also be considered, to obtain an effective protection against oxidation.

Document FR2708291 describes another chromium deposition method on metal parts, by using a conventional magnetron with enhancement by gaseous plasma. However, the method described is based on zinc-coated substrates. In addition, this method seems to be adapted to deposit thin layers only, of thickness less than 1 μm, which is low. Particularly, this document does not settle the problem of density of the deposited layer.

### SUMMARY OF THE INVENTION

One of the aims of the invention is to overcome the problems of the prior art by proposing a method for depositing a material comprising chromium on a substrate, which is efficient, inexpensive, and the chromium-based layer thus formed of which has a density at least equivalent with respect to the deposition techniques of the prior art.

To this end, the applicant has developed a method for depositing a chromium-based material from a target onto a metal substrate, by continuous magnetron sputtering, using a plasma generated in a gas.

According to the invention, the ratio between the flow of gaseous ions directed toward the substrate and the flow of neutral chromium atoms directed toward the substrate is adjusted between 0.5 and 1.7 (inclusively), and a bias voltage is applied to the substrate of between −50V and −100V (inclusively).

The method according to the invention is simple to implement and inexpensive, since the technologies used are proven and the necessary material is widely available on the market. Moreover, these technologies can be adapted to the treatment of parts of large dimensions without particular difficulties, in particular, because it implements the magnetron sputtering technique, combined with an independent plasma source, or conventional magnetron deposition combined with an independent plasma source, and not HIPIMS.

Moreover, the adjustment, on the one hand, of the ratio between the flow of gaseous ions and the flow of neutral chromium ions of between 0.5 and 1.7, and on the other hand, of a bias voltage of the substrate of between −50 volts and −100 volts, which returns to adjusting the energy of the gaseous ions between 50 eV and 100 eV (electronvolts), makes it possible to obtain a particularly dense chromium-based layer, which gives it a better protection against oxidation.

This therefore relates to a method for improving the density of a chromium-based material layer, in the scope of a deposition by continuous magnetron sputtering.

The flow of gaseous ions is directed toward the substrate and is accelerated by the latter by the bias of the substrate. These interactions between the ions and the substrate occur in the proximity of the substrate. These ions, which bombard the growing layer, mainly come from the plasma source and, for a minor share, from the magnetron cathode. The flow of gaseous ions therefore comprises the ions of the gaseous mixture, wherein the plasma is generated, such as argon ions, for example. It can also, for example, comprise nitrogen ions, when nitrogen is used to produce plasma.

The flow of neutral chromium atoms is oriented from the cable toward the substrate. It comprises chromium-based material atoms coming from the target.

The values of gaseous ion flows and of neutral chromium atom flows are average flow values, calculated from measurements. Indeed, in practice, it is understood that insofar as the substrates to be covered are movable in the installation, while the magnetron cathode and the plasma source are fixed, said substrates do not receive the same quantities of ions and of chromium according to their positioning at a given instant.

The bias voltage of the substrate, or more simply, bias of the substrate, is defined as being the potential difference applied between the substrates and the ground of the device implementing the method. This bias can be continuous or with a pulsed direct current. In the latter case, the bias voltage is the average value of the voltage applied to the substrates. The bias current is the (average) intensity corresponding to the bias voltage.

The (kinetic) energy of the gaseous ions is given to them by acceleration in the electrical field which prevails around the substrates. It is linked to the bias voltage and is calculated by multiplying the absolute value of the potential difference between the plasma and the absolute value of the bias voltage by the electrical charge of the particle or of the species considered. Generally, it is considered that the plasma potential with respect to the ground is marginal before the potential difference between the ground and the parts. This returns to considering that the energy from the ions in eV corresponds to the potential different in volts, for a single-charged ion.

In a particular embodiment, adapted to the field of nuclear reactors, the substrate comprises a zirconium alloy, and the chromium-based material is deposited on and in contact with said zirconium alloy.

In order to further improve the density of the deposition, the following features can be present individually or according to their technically possible combinations:
the ratio between the flow of gaseous ions and the flow of neutral chromium atoms is between 0.7 and 1.5;
the substrate is subjected to a bias voltage of between −50V and −80V.

In order to simplify the implementation of the method and, in particular, the taking of measures of the evaluation of magnitudes, the following features can be taken individually or according to their technically possible combinations:
the flow of gaseous ions is determined from the bias current of the substrate, and the flow of neutral chromium atoms is determined from the deposition speed of the material onto the metal substrate;
the flow of gaseous ions can be determined by dividing the bias current by the total surface area of the substrates, in order to obtain an average bias current density, then by dividing said bias current density by the charge of an electron.
the flow of neutral chromium atoms is determined by multiplying the deposition speed of the material onto the metal substrate by the density of the material, and by then dividing by the molar mass of the material, then by multiplying the result obtained by Avagadro's number.

Such that the protection against oxidation is sufficient durable in case of nuclear accident, the material deposited on the substrate forms a layer called thin layer, preferably having a thickness of between 4 μm and 20 μm, and preferably between 11 μm and 17 μm.

To simplify the implementation of the method, the plasma is preferably generated by microwaves.

Preferably, the gas comprises argon.

In a particular embodiment, the gas comprises nitrogen, or nitrogen and

argon, and the material comprises chromium nitride.

With an aim of productivity and rationalisation of equipment, the deposition can be performed simultaneously over several substrates, and the substrates are in movement during the deposition in a first rotation, and preferably in two combined rotations and parallel axes, and even more preferably, in three combined rotations and parallel axes.

In order to be compatible with the treatment of parts of large dimensions, the substrate preferably has a length greater than ten times its width or its height, or the substrate has a length greater than ten times its diameter.

In certain particular cases, such as that of the nuclear reactor fuel sheaths, the substrate is preferably a tube of external diameter less than 40 mm (millimetres) and of length greater than 1 m (metre).

In order to prevent the diffusion of chromium in the substrate at a high temperature, the method preferably comprises a prior step of depositing a first layer on the substrate, the first layer comprising tungsten, tantalum, molybdenum, vanadium or hafnium. This first layer forms a barrier layer between the substrate and the chromium-based material subsequently deposited.

The invention also relates to a method for manufacturing a nuclear fuel sheath comprising a metal substrate covered with a layer comprising a chromium-based material, the method comprising a step of depositing said chromium-based material from a target on said metal substrate, by continuous magnetron sputtering, according to the technical features of the deposition method described above.

### BRIEF DESCRIPTION OF THE DRAWINGS

FIG. 1 is a schematic representation, as a top view, of an installation for the implementation of the method according to the invention.

FIG. 2 is a graph illustrating the development of the reflectivity of chromium-based material layers deposited on substrates according to the cathodic power, obtained during a first series of tests carried out at a bias voltage of −55V.

FIG. 3 is a graph illustrating the development of the reflectivity of chromium-based material layers deposited on substrates, obtained during a second series of tests carried out at cathodic powers of 8 kW and 10 kW, according to the bias voltage.

FIG. 4 is a graph illustrating the reflectivity of chromium-based material layers deposited on substrates, obtained during different tests carried out with a ratio between the flow of gaseous ions and the flow of neutral chromium atoms of around 1.0, according to the bias voltage.

FIG. 5 is a graph summarising the specular reflectivities obtained during the tests, according to the ion flow/neutral (chromium) flow ratio, for different ion energies.

FIG. 6 is a graph summarising the roughnesses AFM obtained during tests.

FIG. 7 is a graph summarising the specular reflectivities obtained during tests, according to the ion flow/neutral (chromium) flow ratio according to which the substrates are in double rotation (2R) or in triple rotation (3R).

FIG. 8 is a cross-section of a substrate treated according to the method of the invention.

FIG. 9 is a cross-section of another substrate treated according to the method of the invention.

### DETAILED DESCRIPTION OF THE PREFERRED EMBODIMENT

In the field of surface treatment, there are several types of technologies, and each has its advantages and its disadvantages. In the scope of treating parts, and in particular, long parts as it can be for fuel sheaths, the applicant has sought to optimise known deposition methods.

Polluting technologies, or existing experimental solutions, but not yet being industrialised, have been discarded for clear, difficult industrial application reasons.

Based on the known and industrialisable technology of deposition by plasma-enhanced conventional magnetron sputtering, the applicant has carried out different series of tests and interpretations aiming to obtain a deposition of a chromium-based material (M), forming a dense layer on a substrate (S).

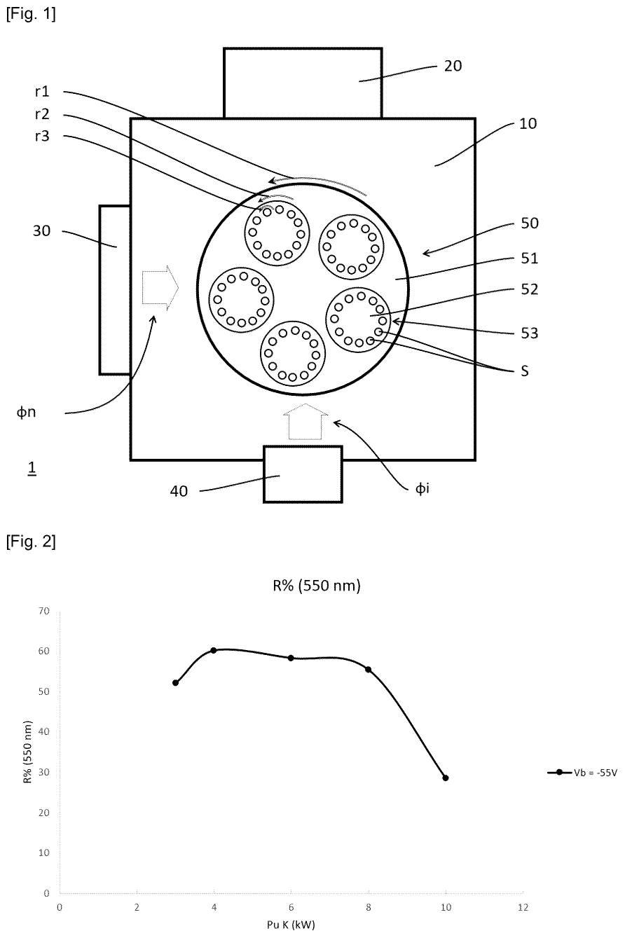

In reference to FIG. 1, the installation (1) used to implement the method comprises a secondary vacuum enclosure (10), provided with a pumping system (20), a conventional magnetron sputtering source (30), a plasma source (40) generating a plasma (P) of gaseous ions, and a substrate carrier (50) on which the substrates (S) to be treated are mounted.

The pumping system (20) makes it possible to obtain, in the secondary vacuum enclosure (10), i.e. a vacuum with an order of magnitude of between 10⁻⁸ mbar and 10⁻³ mbar. The pumping system (20) is also capable of introducing a gas in a vacuum enclosure (10). The gas is intended to be ionised within the plasma (P). This preferably relates to argon, but the gas can also comprise nitrogen, combined with argon or instead of the latter, such that the material (M) comprises chromium nitride.

The magnetron sputtering source (30), or magnetron (30), is of the conventional type, provided with a generator, the power of which is around 20 kW. The power of the generator is adjustable. Several generators can also be associated to deliver more power on a deposition source. For a conventional magnetron (30), long cathodes, i.e. capable of treating long parts of several metres, are available. These long cathodes can require a suitable power generator, for example, 100 kW. According to the installation used, it is possible to add several cathodes to deposit quicker, in which case each cathode is powered by its generator (for example, two 50 kW generators).

The plasma source (40) is of any suitable type, but the plasma (P) is preferably generated by microwaves.

The substrate carrier (50) is biased, i.e. that a negative voltage or potential difference is applied to its terminals, in order to accelerate the gaseous ions of the plasma and thus create a flow of gaseous ions (i) in the direction of the substrate carrier (50). This acceleration of gaseous ions occurs in the vicinity of the substrates (S), since the electrical field which results from the bias of the parts extends over a short distance, of around 1 to 3 mm.

Whether in HIPPIMS or in conventional magnetron sputtering, ions are attracted onto the target made of material (M) of the magnetron, in order to sputter it and emit the atoms which form the deposition on the substrate (S). It is not these ions that the applicant is interested in, in the present invention. Indeed, whether in HIPPIMS or in conventional magnetron, these are the ions attracted onto the substrate (S) where the material (M) deposition grows, which is important for the quality of the layer deposited. In the scope of the application, the ions are constituted of gaseous species like argon, or optionally, argon and nitrogen, even just nitrogen. The gas or the gas mixture is chosen according to the material that is sought to be deposited, in particular chromium or chromium nitride.

The role of these ions is to bombard the material (M) deposition growing on the substrate to compact it, and thus increase the density of the forming material (M) layer. Care must be taken to not eject the material (M) already placed on the substrate (S), in order to not slow down the deposition or degrade the quality of the ongoing deposition.

Generally, the ions of the plasmas are “slow”, they therefore have no power to compact a growing material (M) layer. Even if the ions in HIPPIMS are not as slow as in conventional magnetron, with or without ion enhancement, their energy is insufficient. Thus, and as indicated above, a negative voltage is applied to the substrate (S) to be coated, which attracts and accelerates the positive ions toward said substrates (S).

The bias voltage is between −50V and −100V, preferably between −50V and −80V. The bias of the substrate carrier (50), and therefore of the substrates (S), makes it possible to accelerate the gaseous ions toward the substrate (S) in its vicinity, making it possible for the ions to bombard the growing deposition and thus to densify the material layer during its deposition.

In the case of the bias of a substrate (S) in a plasma (P), the bias voltage is applied between the substrates (S) and the ground. A potential difference is established between the substrates (S) and the plasma (P). It is in this potential drop zone, over around 1 to 3 mm of the surface area of the substrates (S), that the ions are accelerated.

The kinetic energy of the ions is assimilable to the potential difference between the plasma (P) and the substrates (S). In most plasmas, the potential of the plasma is not known, but it is generally a few volts, for example, +5V to +10V. In practice, the potential of the plasma (P) is assimilated to 0V when the voltage applied to the substrates (S) reaches a few tens of volts in absolute value.

This approximation is valid at low pressure, as the ions are not slowed down by collisions in the acceleration phase in the proximity of the substrates (S).

With the acceleration of these ions being proportional to their charge and to the potential difference, the bias voltage is assimilated to the energy given to the ions during the deposition, by multiplying this bias voltage by the charge of an electron. Indeed, in the technical field considered, the ions are generally single-charged.

The substrate carrier (50) is preferably of the revolving type, i.e. that it comprises a first plate (51) driven in a first rotation (r1). Advantageously, this first plate (51) embeds spinners (52) driven in a second rotation (r2), of axis parallel to the axis of the first rotation (r1), and also advantageously the spinners (52) themselves embed supports (53) driven in a rotation (r3) of axis parallel to the axes of the first and second rotations (r1, r2).

Thus, the substrates scroll in front of the magnetron (30) in order to receive the material (M), then scroll in front of the plasma source (40), such that the impacts of gaseous ions compact the material (M) layer deposited. The substrate carrier (50) can however be of any suitable type, according to the substrates (S) to be treated.

In order to be able to easily evaluate the density obtained within the material (M) layer deposited on the substrate (S), two indirect techniques are used according to the geometry of the specimen and to the thickness of the deposition layer:
the measurement of the reflectivity; and
the measurement of the roughness by Atomic Force Microscope (AFM roughness).

These two measuring means are complementary and make it possible to evaluate, with ease, the development of the density of the layers obtained. In principle, when a layer becomes more porous, in particular between the columns which constitute it, the top of the columns is rounded, which creates both the roughness and the diffusion of light. Naturally, these means are useful and quick indicators of the development of the density of the layers, and must be used in comparison, on the condition of preserving a certain number of constant parameters, such as the roughness of the substrates (S), preferably mirror-polished, or also the quantity of material deposited.

The reflectivity measurement is that of specular reflectivity, for example with a 550 nm wavelength. A solid and polished chromium, therefore ideally smooth, reflect between 60 and 65% of light at 550 nm. A reflectivity greater than 50%, and preferably greater than 55%, will therefore be considered as satisfactory in the scope of the tests.

However, when the material (M) layer becomes thick in the sense of the invention, i.e. of the order of magnitude of 10 μm and beyond, the crystals or grains formed by the material become dimensions such that they have facets on the surface of the deposited layer, and these facets reflect light in directions which are slightly different from the specular direction. The specular reflectivity can therefore drop, while the analysed layer is very dense. The measurement of the specular reflectivity must therefore be used to compare layers which are close in thickness.

The AFM roughness is a three-dimensional analysis of the surface state of the sample. A low roughness corresponds to the surface state of the layer having homogenously grown, therefore dense. Conversely, a high roughness corresponds to the surface state of a layer having a sparse column structure.

As needed, it is also possible to cut the samples, for example, by focused ion beam (FIB). These cuts make it possible to observe the morphology of the deposited layer, to verify the appearance and the size of the crystals obtained, as well as the absence of porosities.

Within the installation (1), several series of tests have been carried out. The substrates (S) used are specimens being, for some, metal tubes representative of actual parts to be coated, and for others of small, polished flat samples, which enable characterisations which are easiers than on the tubes.

The specimens are cleaned before being put under vacuum. For flat specimens, a degreasing with a solvent is proceeded with, for example with ethyl acetate, and a rinsing with ethanol. For the tubes, means traditionally used in the industry are proceeded with, namely an ultrasound degreasing in a detergent, then rinsings in tap water and in demineralised water. To finish, the drying of clean parts in done in hot air. The various specimens are installed on the substrate carrier (50) of the illustrated preferred embodiment.

The pumping system (20) performs a preliminary pumping up to a pressure of around 10⁻³ mbar before starting a heating of the inside of the enclosure (10). The substrate carrier (50) is moved in a triple rotation mode, and it remains there until the end of the treatment. The substrates (S) and the inside of the enclosure (10) are also heated for 2 hours at 150° C. with the aim of accelerating the desorption of the surfaces of the substrates (S).

The residual vacuum is thus reduced to less than 3×10⁻⁵ mbar.

The surface of the substrates (S) is then cleaned by a plasma etching, then the substrates (S) are coated by magnetron sputtering.

The table represented below summarises the deposition conditions performed for all of the tests. In this table:
“Pu K” is the power of the cathode of the magnetron (30);
“P MO” is the power of the plasma source (40);
“Vd” is the speed of the material (M) deposition, measured during the deposition;
“Jb” is the bias current density, calculated according to the method explained above;
“R %” is the specular reflectivity of the deposited layer, measured after deposition at 550 nm in wavelength;
“Sa AFM” is the AFM roughness of the deposited layer, measured after deposition;
“φi/φn” is the ratio between the flow (φi) of gaseous ions and the flow (φn) of neutral chromium atoms;
“Ei (#Vb)” is the absolute value of the bias voltage of the substrates (S), and which is assimilable to the energy of the gaseous ions by multiplying this value by the electrical charge of the species in question.

TABLE 1

| | Pu K | P MO | Vd | Jb | R % | Sa AFM | φ(i) / | Ei (#Vb) |
|---|---|---|---|---|---|---|---|---|
| No | (kW) | (W) | (μm/h) | (mA/cm²) | (550 nm) | (nm) | φ(n) | eV (−V) |
| 1 | 10 | 0 | 1.7 | 0.05 | 2 | 32 | 0.07 | 100 |
| 2 | 10 | 1200 | 1.4 | 0.38 | 52.2 | 8.6 | 0.71 | 100 |
| 3 | 10 | 1200 | 1.5 | 0.34 | 28.4 | 15 | 0.64 | 55 |
| 4 | 10 | 1200 | 1.4 | 0.38 | 44.2 | 9.3 | 0.74 | 125 |
| 5 | 10 | 1200 | 1.4 | 0.35 | 32.8 | 8.2 | 0.67 | 75 |
| 6 | 8 | 1200 | 1 | 0.37 | 50.9 | 7.6 | 0.97 | 100 |
| 7 | 8 | 1200 | 1 | 0.38 | 41.1 | 11 | 1.01 | 125 |
| 8 | 8 | 1200 | 1 | 0.35 | 55.7 | 7.5 | 0.92 | 75 |
| 9 | 8 | 1200 | 1.2 | 0.33 | 55.3 | 7.8 | 0.78 | 55 |
| 10 | 6 | 1200 | 0.9 | 0.32 | 58.2 | 6.5 | 1.01 | 55 |
| 11 | 4 | 1200 | 0.6 | 0.31 | 60.1 | 7.2 | 1.45 | 55 |
| 12 | 3 | 1200 | 0.4 | 0.30 | 52 | 8.2 | 1.88 | 55 |
| 13 | 6.5 | 2000 | 1.2 | 0.28 | 59.7 | 6.8 | 1.46 | 55 |
| 14 | 12 | 3600 | 1.8 | 0.94 | 60.3 | 6.9 | 1.43 | 55 |

The substrates (S) thus coated are characterised in thickness of deposited layer, either by Calotest for layers of moderate thickness, up to around 5 μm, or by micrographic cutting for high thicknesses, beyond 5 μm.

On the flat specimens, characterisations are also carried out by measurements of specular reflectivity and AFM roughness. Indeed, the sparse layers have a column structure, the top of the columns of which diffuses light, which decreases the specular reflectivity. When the layers are densified, the top of the columns is flattened and the reflectivity increases. A similar principle applies for AFM roughness measurements taken on 5 μm images from the side.

In the first deposition series, the microwave power is adjusted to the maximum on a 1200 W generator. The flow of gaseous ions (φi) is almost constant, although in reality, it increases slightly when the bias voltage increases in absolute value.

It is sought to optimise the density of the layers by making the energy of the gaseous ions vary, through the bias voltage. The flow of neutral chromium atoms is adjusted through the power applied to the cathode of the magnetron (30). For tests 1 to 10, the deposition thicknesses are between 4.8 and 5.0 μm. When the power of the cathode of the magnetron (30) is modified, the deposition duration is consequently adjusted, to preserve the same layer thickness.

Test 1 gives a very porous chromium layer on the substrates (S) treated in triple-planetary rotation. It corresponds to what is mentioned in document EP3195322 in drawing 1A. The low density of the layer is explained, in particular by a very low quantity of ions (no plasma enhancement), and is characterised by a very rough surface, which diffuses and absorbs light, as the low reflectivity shows.

The “triple” rotation configuration is the preferable embodiment for the installation described in the present text, in reference to FIG. 1, in that it makes it possible to maximise the number of parts treated in one same treatment charge, and therefore to maximise productivity. It will however be understood that the implementation of the method of the invention is not limited to a “triple” rotation configuration installation.

Test 2 shows the effect of adding an ion enhancement by plasma (P), arbitrarily adjusted to the maximum power of the 1200 W generator. A considerable increase of the density of the layer is observed, which is characterised by a less clear deposition speed. Indeed, the same mass per surface unit is deposited on the substrates (S). But, since the density of the layer is greater, its thickness is less. The growth speed of the layer in μm/h is therefore reduced. It is noted that the with the layers being less columnar, their smoother surface better reflects light: the specular reflectivity is passed from 2% to 52.2%.

Tests 2 to 5 aim to test the effect of the energy of the ions, which is adjusted through the bias voltage of the substrate carrier (50). It is noted that the layers of tests 3 to 5, done at −55, −75 and −125V of bias, are rougher than the deposition of test 2.

FIG. 2 is a graph representing the reflectivity obtained by making the power of the cathode of the magnetron (30) vary, to a constant bias of the substrates (S) of −55V.

The applicant has discovered, thanks to the tests carried out, that the specular reflectivity, and therefore the density of the material (M) layer, reaches an optimum for cathodic powers of 4 to 8 kW, then tends to decrease beyond. The evaluation of the sole cathodic power of the magnetron (30) is therefore not sufficient to succeed in densifying the material (M) layer. This graph shows the unclear relationship that there is between the cathodic power and the ion enhancement to obtain a dense layer.

In order to use quantitative measurements and that scaling the method is possible, these magnitudes of cathodic power and of ion enhancement are conveyed:
in flow (φi) of gaseous ions for the ion enhancement by plasma (P), and
in flow (φn) of neutral chromium atoms for the cathodic power of the magnetron (30).

In this case, the flow (φn) of neutral chromium atoms is determined from the deposition speed of a layer considered dense and expressed in cm/s, multiplied by the density of the chromium (7.15 g/cm³), divided by the molar mass of the chromium (51.9961 g/mole) and multiplied by the Avogadro's number (referenced N_{A}=6.022×10²³ mol⁻¹), which gives a number of chromium atoms per cm² and per s.

The total bias current is divided by the total biased surface, which gives an average current density on the substrates. By dividing it by the elementary electrical charge (1.6×10⁻¹⁹ C), a number of single-charged ions is obtained, which hit 1 cm² of substrate (S) surface area per second.

Indeed, although the plasma (P) is located at the plasma source (40), and although the bombardment of substrates (S) occurs in the proximity of it, the total current collected by the substrates (S) is the same as in the case where all of the surface constantly receives an average ion bombardment, therefore an average current density.

The calculation of the flow (φn) of neutral chromium atoms is made implicitly in the same way: by dividing the thickness of the deposition by the deposition duration, an average deposition speed is determined, despite the fact that the deposition is formed during the passage of the substrates (S) in front of the magnetron cathode (30). However, there is the whole surface of the substrates (S) which is coated during the total duration of the deposition, and it is therefore as if the whole surface permanently received the flow (φn) of neutral chromium atoms thus calculated.

Under the test conditions, the microwave power for generating the plasma (P) has been fixed to the maximum. To adjust the ratio between the flow (i) of gaseous ions and the flow (φn) of neutral chromium atoms, the cathodic power of the magnetron (30) has been reduced to 8 kW (tests 6 to 9) at the same time as the acceleration voltage of the gaseous ions has been adjusted between −55 and −125V. It is for a voltage of between −55V and −75V that the deposition seems the most compact. Ions with too much energy degrade the quality of the deposition.

As a side note, the bias current density is between 0.05 mA/cm² and 2 mA/cm². However, as the tests show, it is insufficient to obtain a good densification of the deposited layer, and must be adjusted in accordance with the deposition speed in order to fulfil the ratio criterion between the flow of gaseous ions and the flow of neutral chromium atoms pi/on of between 0.5 and 1.7.

In this regard, by comparing test 5 to tests 6 to 9, it is noted that a higher cathode power (for test 5), and therefore a higher current density of the cathode, improves the deposition speed, but does not make it possible to obtain a layer of an acceptable density. This is due to a too high quantity of neutral chromium atoms (ratio of 0.67) arriving on the substrate per time unit. For tests 6 to 9, the cathode power, and therefore the current density of the cathode are lower than for example 5, but the ratio φi/φn is higher, and greater than 0.7, which improves the density of the deposited layer.

When the ratio between the flow (φi) of gaseous ions and the flow (φn) of neutral chromium atoms continues to increase, by adapting the cathodic power of the magnetron (30), the density of the layers continues to grow (tests 10 and 11).

In test 12, the decrease of the cathodic power of the magnetron (30) produces a degradation of the growth of the material (M) layer, by excess ion bombardment. A ratio between the flow (φi) of gaseous ions and the flow (φn) of neutral chromium atoms of 1.88 is therefore excessive.

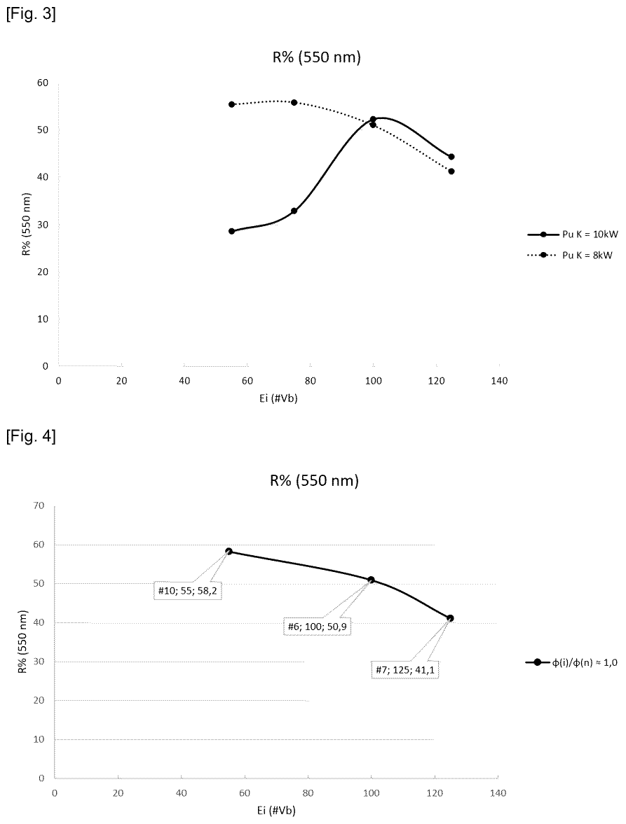

FIG. 3 is another graph, representing the reflectivity obtained by making the bias voltage of the substrates (S) vary, at a constant power of the cathode of the magnetron (30), either at 8 kW, or at 10 kW. These graphs complete the teaching of FIG. 2, as there, it is seen that a cathodic power of 10 kW can, all the same, be used to obtain a dense deposition, if the substrates (S) are biased at −100V. This shows that a slight lack of ions can be partially compensated by the increase of the bias voltage. However, the reflectivity remains a little lower.

However, a cathodic power of 8 kW can give bad results for so high voltages. This shows that moreover, the ratio between the flow (φi) of gaseous ions and the flow (φn) of neutral chromium atoms, a bias voltage range is to be respected, in order to avoid, as under the conditions of test 7, ions with too much energy degrades the surface of the deposited layer.

This point is confirmed by FIG. 4, which is a graph illustrating the reflectivities obtained by three tests numbered 6, 7 and 10, and for which the ratio between the flow (φi) of gaseous ions and the flow (φn) of neutral chromium atoms is close to 1.0. There it is seen that the too high bias voltage of test 7, at −125V, gives too much energy to the gaseous ions, such that instead of densifying the material (M) layer, they degrade it.

Thus, the layers produced at an ion energy of between 50 and 75 eV with an ion flow over neutral flow ratio of between 0.7 and 1.5 combine the good growth features to have a chromium-based dense material (M) deposition (tests 8 to 11 which are in accordance with the invention). The layers of tests 1 to 7, although being deposited quickly, are not all conform, as some do not have the features of an ideally compact layer. Test 12 exits from the conformity zone, its features are degraded a little and its deposition speed also has less interest.

In tests 13 and 14, always for layers which are 5 μm thick, the cathodic power of the magnetron (30) is increased to increase the deposition speed. In order to preserve a flow (φi) of gaseous ions and the flow (φn) of neutral chromium atoms, the microwave generator of the plasma source (40) of 1200 W has been replaced by a 2000 W generator for test 13. The setpoint of the microwave generator of the plasma source (40) has been fixed at 2000 W.

To go further, a second plasma source (40) is added in test 14. This second plasma source (40) is also equipped with a 2000 W microwave generator. For test 14, each microwave generator has an output of 1800 W, which brings the total power to 3600 W for ion enhancement by plasma (P).

By increasing the total power of ion enhancement by plasma (P), it has become possible to increase the power on the cathode of the magnetron (30), and through that, the deposition speed in triple rotation which passes from 0.6 μm and reaches 1.8 μm/h.

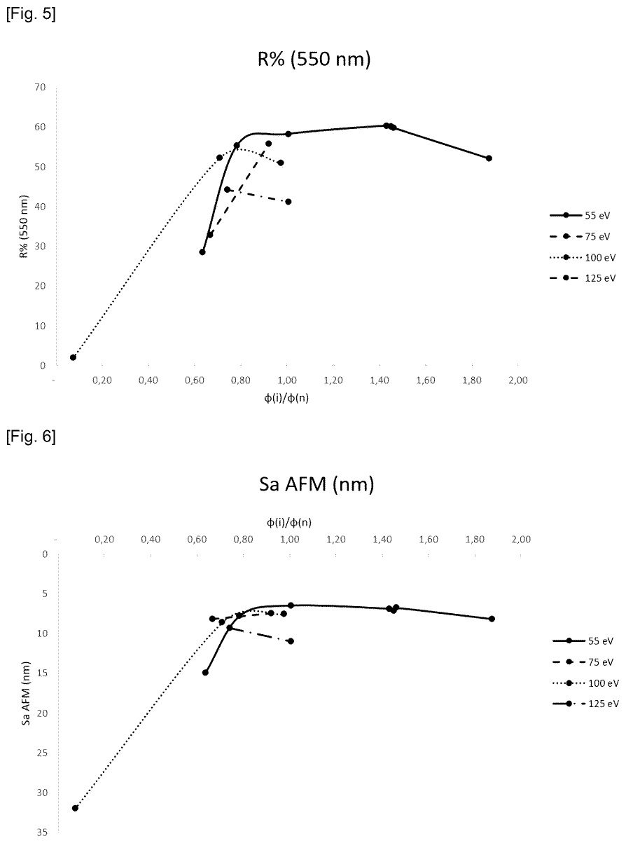

FIGS. 5 and 6 are two graphs summarising the tests carried out, respectively representing the specular reflectivity in FIG. 5, and the AFM roughness in FIG. 6. On the latter, the ordinate scale has been inversed, such that the correlation between the specular reflectivity and the AFM roughness can be seen better, although this relates, in reality, to an inverse correlation: the lower the AFM roughness is, the greater the specular reflectivity is.

To verify the density of the layer obtained, test 11 has been replicated in a test 11′, by increasing the deposition duration such that the thickness passes from 5.0 to 14.0 μm. A slight drop in reflectivity is observed, it passes from 60.1% for a layer which is 5 μm thick at 47.3% for a thickness close to 14 μm. The AFM roughness remains moderate at 10 nm for Sa for a thickness close to 14 μm, instead of 7.2 nm for a layer which is 5 μm thick.

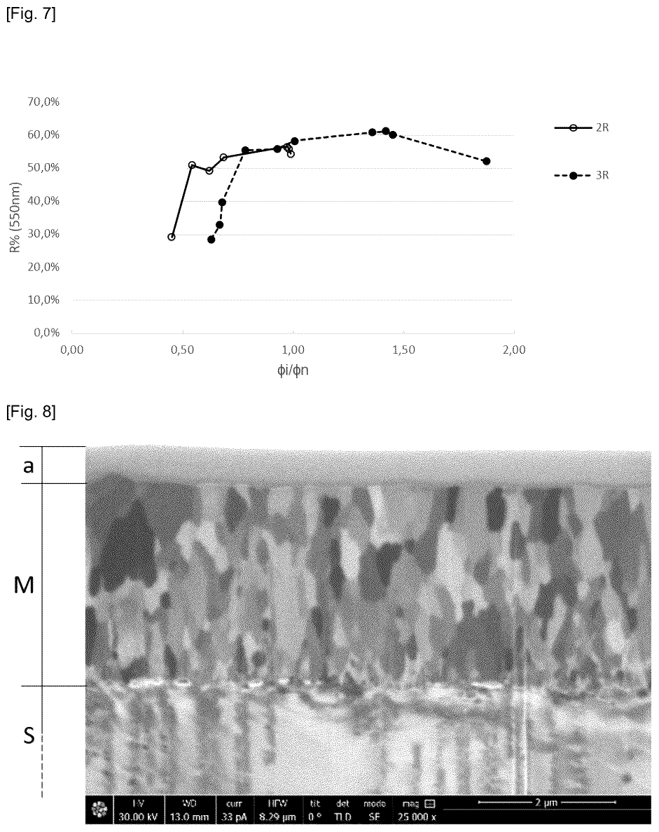

In parallel to the triple rotation tests, substrates (S) have been coated in a double rotation configuration, with the aim of verifying if there is an impact from the rotation mode. The results are summarised in FIG. 7, which shows the development of reflectivity according to the flow ratio. As can be seen in this figure, in double rotation, the obtaining of a reflectivity greater than 50% is done for φi/φn ratios of between 0.5 and 1.0, and therefore for ratios lower than in triple rotation. In order to obtain a maximum reflectivity, preferably a ratio of between 0.7 and 1.0 will be chosen in this mode. Also, it is observed that the maximum is lower in double rotation reflectivity than in triple rotation, but this is due to the greater thickness of the deposition.

In fact, the two rotation modes are differentiated by the charge filling rate. In the double rotation mode, the charge is constituted of cylinders of 110 m in diameter, on which the substrates (S) are fixed. It can be considered that this relates to an optimal filling. In the triple rotation mode of the other side, the charge is constituted of a circular arrangement of 12 tubes of 10 mm in diameter with a space of around 15 mm between the tubes. This therefore relates to a relatively perforated filling. In this case, the deposition speed is lower and there is probably more deposition which is done in oblique incidence, and by thermalised flow (i.e. that the kinetic energy of the neutral atoms has dropped due to collisions with the gas). It is thus observed that more ions are needed to densify the deposition. The 50% reflectivity threshold is crossed above a ratio of 0.7 and the reflectivity remains high, up to a ratio of around 1.7 before being degraded due to the over-bombardment by the gaseous ions. The optimum is obtained for ratios of between 1.0 and 1.5.

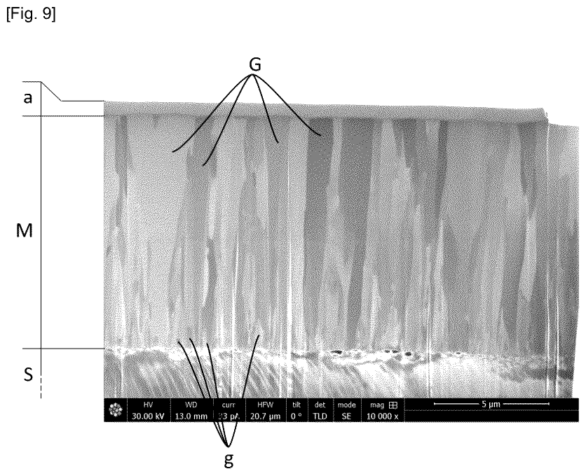

This perforated mounting is necessary in the case of treating long tubes, as with their very long length and the possible arrow which results from this, a significant distance between tubes during treatment seems necessary, in order to avoid contacts between parts. FIGS. 8 and 9 are cuttings of the coating, done by FIB to observe the morphology of the material (M) layer, deposited on the substrate (S). For technical reasons, an aluminium (a) layer is added onto the samples in order to proceed with FIB cutting. On these observations made under a scanning electron microscope, the corrections of the tilting of the plate toward the detectors have not been made, such that these cuts only serve to observe the appearance of the deposited layer, by measuring its thickness.

FIG. 8 is a cutting of the layer obtained during test 11 and illustrates, in particular, the appearance of the chromium-based material (M) grains which are formed on the surface of the substrate (S). The thickness of the deposition is low, such that all the grain growth directions are present: the grains are oriented in all directions.

FIG. 9 is a cutting of a layer obtained during test 11′.

It is noted that the base of the deposition is constituted of smaller grains (g) than on the rest of the thickness of the layer. The layer is developed by selection of favoured growth directions, such that in the upper part, the layer no longer comprises large grains (G), and which are extended in the direction of the growth of the layer. The top of the grains (G) tends to form well-marked facets which reflect light in directions slightly different to the specular direction. This explains the drop in specular reflectivity observed. However, it is clearly seen that the grains touch one another, and that no porosity can be seen between the grains.

Materials other than chromium are known to enable the oxidation resistance of the metal substrates, like for example, chromium nitrides. It is possible to pass the method described in this case into reactive mode by introducing nitrogen into the enclosure (10), in addition to argon.

It would therefore easily be possible to add, for example, a chromium nitride layer on the dense chromium layer, even to make a multilayer deposition, by alternating the two materials.

According to a variant not represented, a prior deposition on the substrate (S) of a first layer comprising a metal such as tungsten, tantalum, molybdenum, vanadium or hafnium is proceeded with, before the deposition of the chromium-based material (M).

This first layer disposed between the substrate (S) and the material (M) is intended to form a barrier layer, such that at high temperature, the chromium of the material (M) does not diffuse in the substrate (S), which could lower its melting temperature and therefore, in the particular case of a fuel sheath, speed up the worsening of an incident. This first layer is deposited by implementing a second magnetron cathode (source of the material of the first layer) and by using the same plasma source (40).

Moreover, the method can be performed differently from the examples given without moving away from the scope of the invention, which is defined by the claims.

In a variant not represented, the plasma (P) of the ion enhancement is not generated by microwaves. Indeed, it is not the power consumed by the plasma source (40) which is important, but the quantity of gaseous ions available at the parts, hence the interpretation of the flow (φi) of gaseous ions proposed by the applicant.

Other gaseous ion sources can be used. Closed field magnetron sputtering is also possible. These variants can require to correctly adjust the imbalance of the magnetrons and the looping of the field lines between cathodes to arrive at the flow ratio range.

Furthermore, the technical features of the different embodiments and variants mentioned above can be, totally or for some of them, combined together. Thus, the method and the installation (1) can be adapted in terms of cost, functionalities and performance.

1-12. (canceled)

13. A method for depositing a chromium-based material from a target onto a metal substrate by continuous magnetron sputtering using a plasma generated in a gas,
wherein a ratio between a flow of gaseous ions directed toward the metal substrate and a flow of neutral chromium atoms directed toward the metal substrate is between 0.5 and 1.7; and
wherein a bias voltage is applied to the metal substrate at a range between −50 V and −100 V.

14. The method of claim 13, wherein the metal substrate comprises a zirconium alloy, and wherein the chromium-based material is deposited on and is in contact with the zirconium alloy.

15. The method of claim 13, wherein the ratio between the flow of gaseous ions and the flow of neutral chromium atoms is between 0.7 and 1.5.

16. The method of claim 13, wherein the bias voltage is between −50 V and −80 V.

17. The method of claim 13, wherein the chromium-based material deposited on the metal substrate forms a layer having a thickness of between 4 μm and 20 μm.

18. The method of claim 17, wherein the layer has a thickness of between 11 μm and 17 μm.

19. The method of claim 13, wherein the plasma is generated by microwaves.

20. The method of claim 13, wherein the gas comprises nitrogen, or nitrogen and argon, and the chromium-based material comprises chromium nitride.

21. The method of claim 13, wherein depositing the chromium-based material is performed on several metal substrates.

22. The method of claim 21, wherein the several metal substrates are in movement during the deposition in a first rotation.

23. The method of claim 21, wherein the several metal substrates are in movement during the deposition in two combined rotations.

24. The method of claim 23, wherein the two combined rotations are of parallel axes.

25. The method of claim 21, wherein the several metal substrates are in movement during the deposition in three combined rotations.

26. The method of claim 25, wherein the three combined rotations are of parallel axes.

27. The method of claim 13, wherein the metal substrate has a length greater than ten times its width or its height.

28. The method of claim 13, wherein the metal substrate has a length greater than ten times its diameter.

29. The method of claim 13, wherein the metal substrate is a tube of external diameter less than 40 mm and of length greater than 1 m.

30. The method of claim 13, wherein the method comprises a prior step of depositing on the metal substrate a first layer comprising tungsten, tantalum, molybdenum, vanadium, or hafnium, thereby forming a barrier layer between the metal substrate and the chromium-based material.

31. A method for manufacturing a nuclear fuel sheath comprising a metal substrate covered with a layer comprising a chromium-based material, wherein the method comprises depositing the chromium-based material from a target on the metal substrate, by continuous magnetron sputtering, according to the method of claim 13.
